(19) United States
(12) Patent Application Publication
(10) Pub. No.: US 2026/0096129 A1
(43) Pub. Date: Apr. 2, 2026

(54) SEMICONDUCTOR DEVICE AND METHOD FOR MANUFACTURING SAME

(71) Applicants: Kabushiki Kaisha Toshiba, Kawasaki-shi (JP); Toshiba Electronic Devices & Storage Corporation, Kawasaki-shi (JP)

(72) Inventors: Yasuhiro ISOBE, Narashino Chiba (JP); Yasunobu SAITO, Inagi Tokyo (JP); Akira YOSHIOKA, Yokohama Kanagawa (JP)

(21) Appl. No.: 19/411,094

(22) Filed: Dec. 5, 2025

Related U.S. Application Data
(63) Continuation of application No. PCT/JP2023/033572, filed on Sep. 14, 2023.

(51) Int. Cl. H10D 30/47; H10D 30/01; H10D 62/10; H10D 62/824; H10D 64/00

(52) U.S. Cl. CPC H10D 30/475; H10D 30/015; H10D 30/476; H10D 30/478; H10D 62/102; H10D 62/824; H10D 64/112; H10D 64/117

(57) ABSTRACT

A semiconductor device includes a substrate; a gallium nitride layer located on a non-polar surface of the substrate, the gallium nitride layer including a plurality of fin parts separated from each other in a first direction parallel to a c-axis direction, the plurality of fin parts extending in a second direction; an electron supply layer located at a Ga-surface of at least one of the fin parts; a source finger part extending in the first direction and contacting the electron supply layer; a drain finger part extending in the first direction and contacting the electron supply layer, the drain finger part being separated from the source finger part in the second direction; and a gate electrode positioned between the source finger part and the drain finger part, the gate electrode facing the electron supply layer in the first direction.

### CROSS-REFERENCE TO RELATED APPLICATION

This is a continuation application of International Application PCT/JP2023/033572, filed on Sep. 14, 2023; the entire contents of which are incorporated herein by reference.

### FIELD

Embodiments described herein relate generally to a semiconductor device and a method for manufacturing a semiconductor device.

### BACKGROUND

In a lateral GaN-HEMT (High Electron Mobility Transistor), a GaN layer is typically grown on a c-surface of the substrate, and so such HEMTs typically have two-dimensional structures, which limit the degree of freedom of the device structure.

### BRIEF DESCRIPTION OF THE DRAWINGS

FIG. 1 is a schematic plan view of a semiconductor device of an embodiment;

FIG. 2 is a line A-A cross-sectional view of FIG. 1;

FIG. 3 is a line B-B cross-sectional view of FIG. 1; and

FIG. 4A to FIG. 9B are schematic cross-sectional views showing the method for manufacturing the semiconductor device of the embodiment.

### DETAILED DESCRIPTION

According to an embodiment, a semiconductor device includes: a substrate; a gallium nitride layer located on a non-polar surface of the substrate, in which the gallium nitride layer includes multiple fin parts separated from each other in a first direction parallel to a c-axis direction, and the multiple fin parts extend in a second direction orthogonal to the first direction; an electron supply layer located at a Ga-surface of at least one of the fin parts; a source finger part that extends in the first direction and contacts the electron supply layer; a drain finger part that extends in the first direction, is separated from the source finger part in the second direction, and contacts the electron supply layer; a gate electrode that is positioned between the source finger part and the drain finger part in the second direction and faces the electron supply layer in the first direction; and a first insulating film located between the gate electrode and the electron supply layer.

Embodiments will now be described with reference to the drawings. The same configurations are marked with the same reference numerals in the drawings.

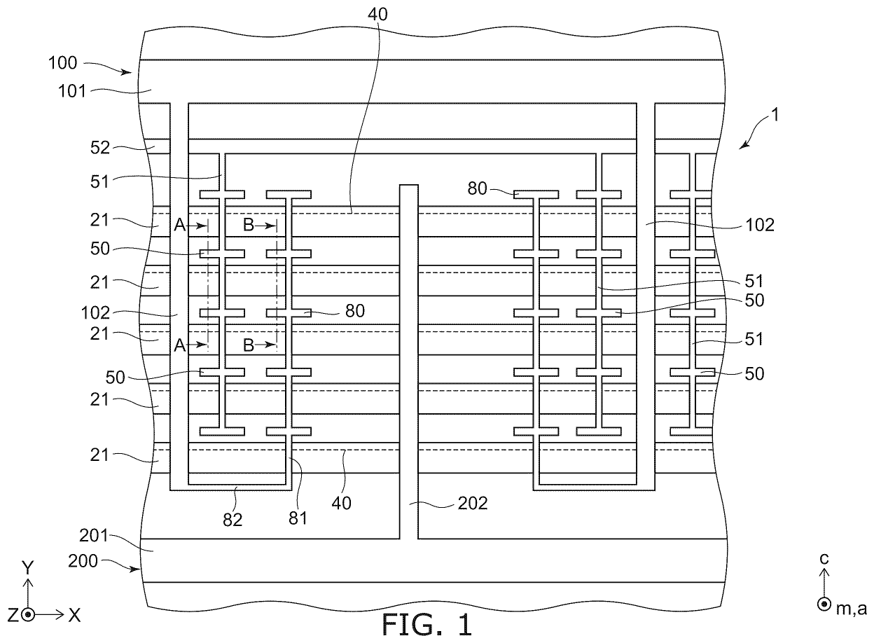

A semiconductor device 1 of an embodiment will now be described with reference to FIGS. 1 to 3.

The semiconductor device 1 of the embodiment includes a substrate 10 and a gallium nitride layer 20. In the specification, a direction parallel to the c-axis direction perpendicular to the c-surface of the gallium nitride layer 20, which is a polar surface, is taken as a first direction Y. A direction orthogonal to the first direction Y is taken as a second direction X. A direction orthogonal to the first and second directions Y and X is taken as a third direction Z. The third direction Z is parallel to the m-axis direction or the a-axis direction of the gallium nitride layer 20. The gallium nitride layer 20 also may be referred to as the GaN layer 20. The gallium nitride layer (the GaN layer) 20 includes nitrogen (N) and gallium (Ga), and may include additives other than nitrogen and gallium. The composition ratio of the additives in the gallium nitride layer 20 is less than the composition ratio of nitrogen and the composition ratio of gallium.

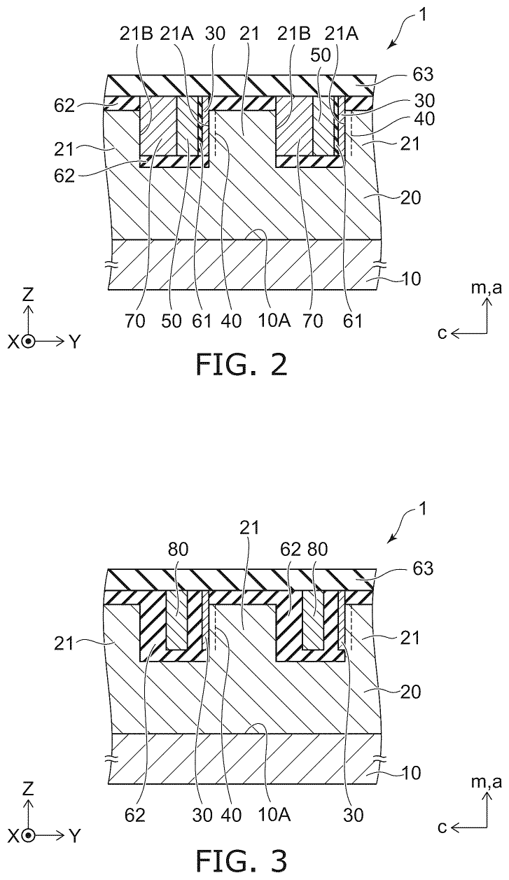

The substrate 10 is, for example, a gallium nitride substrate. As shown in FIGS. 2 and 3, the GaN layer 20 is located on a non-polar surface 10A (an m-surface or an a-surface) of the substrate 10. A sapphire substrate or a silicon substrate of which the off-angle is controlled may be used as the substrate 10.

As shown in FIG. 2, the GaN layer 20 includes multiple fin parts 21 having convex shapes when viewed in cross-section. As shown in FIG. 1, the multiple fin parts 21 are separated from each other in the first direction Y and extend in the second direction X. Among the two side surfaces of the fin part 21 extending in the second direction X, the side surface facing the +c axis direction is a Ga-surface 21A that is terminated with Ga; and the side surface facing the −c axis direction is a N-surface 21B that is terminated with N.

As shown in FIG. 2, the semiconductor device 1 includes an electron supply layer 30 located at the Ga-surface 21A of the fin part 21. The electron supply layer 30 extends in the second direction X along the fin part 21. The bandgap of the electron supply layer 30 is wider than the bandgap of the GaN layer 20. The electron supply layer 30 is, for example, an aluminum gallium nitride (AlGaN) layer. The electron supply layer 30 may be an aluminum nitride (AlN) layer. The piezoelectric polarization effect causes a distribution of a two-dimensional electron gas 40 in the GaN layer 20 at the vicinity of the interface with the electron supply layer 30 (the Ga-surface 21A). The two-dimensional electron gas 40 has a distribution along the third direction Z and extends along the second direction X.

As shown in FIG. 1, the semiconductor device 1 includes a source electrode 100, a drain electrode 200, and a gate electrode 50. In the semiconductor device 1, the structure shown in FIG. 1 is repeated in the second direction X.

The source electrode 100 includes a source pad part 101 extending in the second direction X and multiple source finger parts 102 arranged to be separated from each other in the second direction X. The multiple source finger parts 102 extend in the first direction Y from the source pad part 101.

The drain electrode 200 includes a drain pad part 201 extending in the second direction X, and multiple drain finger parts 202 arranged to be separated from each other in the second direction X. The drain finger part 202 is separated from the source finger part 102 in the second direction X. The multiple drain finger parts 202 extend in the first direction Y from the drain pad part 201 toward the source pad part 101.

For example, the source finger part 102 and the drain finger part 202 contact the upper end parts of the electron supply layers 30 and are electrically connected to the electron supply layers 30. The source finger part 102 and the drain finger part 202 may contact the GaN layer 20. A current flows between the drain electrode 200 and the source electrode 100 via the two-dimensional electron gas 40.

The gate electrode 50 is positioned between the source finger part 102 and the drain finger part 202 that are adjacent to each other in the second direction X. The multiple gate electrodes 50 are arranged to be separated from each other in the first direction Y. Each gate electrode 50 is positioned between the fin parts 21 that are adjacent to each other in the first direction Y. The multiple gate electrodes 50 are connected to a first gate wiring part 51 extending in the first direction Y. The first gate wiring part 51 is connected to a second gate wiring part 52 extending in the second direction X. A gate voltage is applied to the gate electrodes 50 via the second and first gate wiring parts 52 and 51. The multiple first gate wiring parts 51 extend in the first direction Y from the second gate wiring part 52. The multiple gate electrodes 50 that are arranged in the first direction Y are connected to the multiple first gate wiring parts 51. One source finger part 102 is positioned between the gate electrodes 50 adjacent to each other in the second direction X and between the first gate wiring parts 51 adjacent to each other in the second direction X. The distance (the drift length) in the second direction X between the drain finger part 202 and the gate electrode 50 is greater than the distance in the second direction X between the source finger part 102 and the gate electrode 50. The breakdown voltage can be increased thereby.

As shown in FIG. 2, the semiconductor device 1 also includes a first insulating film 61 located between the gate electrode 50 and the electron supply layer 30. The gate electrode 50 faces the electron supply layer 30 via the first insulating film 61 in the first direction Y.

According to the embodiment, the two-dimensional electron gas 40 that has a distribution in the height direction of the fin part 21 (the third direction Z) can be formed at the multiple fin parts 21 provided in the gallium nitride layer 20; and the characteristic on-resistance RonA can be reduced. The characteristic on-resistance RonA is the product of an on-resistance Ron and an effective area A involved in the current conduction.

RonA decreases as the aspect ratio (the ratio of height to width) of the fin part 21 increases and as the pitch of the multiple fin parts 21 decreases. Accordingly, it is favorable to satisfy the relationship C>A+B, in which A is the width in the first direction Y of the fin part 21, B is the distance (or the pitch) between the fin parts 21 adjacent to each other in the first direction Y, and C is the height in the third direction Z of the fin part 21. For example, A and B are about 100 nm; and C is greater than A+B and not more than 1 μm.

A structure of a comparative example may be considered in which a gate electrode faces the side surface of the fin part, a source electrode is located at the bottom of the recess between adjacent fin parts, and a drain electrode is located at the upper surface of the fin part. According to such a comparative example, the height of the fin part must be increased in order to increase the distance between the gate electrode and the drain finger part. In contrast, according to the embodiment, the distance (the drift length) between the gate electrode 50 and the drain finger part 202 can be increased independently of the height of the fin part 21 as shown in FIG. 1. The breakdown voltage can be increased thereby.

As shown in FIG. 2, the semiconductor device 1 also may include a p-type layer 70 located at the N-surface 21B of the fin part 21. The p-type layer 70 is, for example, a p-type GaN layer including magnesium (Mg). For example, the p-type layer 70 contacts the gate electrode 50. Or, an insulating film may be located between the p-type layer 70 and the gate electrode 50; 35 and the p-type layer 70 may not contact the gate electrode 50.

The potential of the gate electrode 50 can be applied from the N-surface 21B side to the fin part 21 via the p-type layer 70. Such a back gate effect can be used to control the concentration of the two-dimensional electron gas 40. As a result, the threshold voltage can be controlled, or a normally-off operation is possible.

The potential that is applied to the p-type layer 70 is not limited to the gate potential, and may be any potential applied by an independent electrode. The source potential (e.g., a ground potential) may be applied to the p-type layer 70.

The semiconductor device 1 also can include a second insulating film 62. The second insulating film 62 is located between the lower end part of the electron supply layer 30 and the GaN layer 20, between the lower end part of the gate electrode 50 and the GaN layer 20, between the lower end part of the p-type layer 70 and the GaN layer 20, and between the lower end part of the first insulating film 61 and the GaN layer 20. The second insulating film 62 also can be located at the upper surface of the fin part 21.

The semiconductor device 1 also can include a third insulating film 63. The third insulating film 63 covers the second insulating film 62 located at the upper surface of the fin part 21, the upper end part of the electron supply layer 30, the upper end part of the gate electrode 50, the upper end part of the p-type layer 70, and the upper end part of the first insulating film 61.

For example, the source finger part 102 and the drain finger part 202 can contact the upper end part of the electron supply layer 30 via an opening formed in the third insulating film 63. For example, the source finger part 102 and the drain finger part 202 can contact the upper surface of the fin part 21 via an opening formed in the third and second insulating films 63 and 62.

As shown in FIGS. 1 and 3, the semiconductor device 1 also may include a field plate electrode 80. The field plate electrode 80 is positioned between the gate electrode 50 and the drain finger part 202 in the second direction X and between the fin parts 21 adjacent to each other in the first direction Y. Multiple field plate electrodes 80 are arranged to be separated from each other in the first direction Y. The multiple field plate electrodes 80 are connected to a first wiring part 81 extending in the first direction Y. The first wiring part 81 is electrically connected to the source finger part 102 via a second wiring part 82 extending in the second direction X. The source potential is applied to the field plate electrode 80 via the second and first wiring parts 82 and 81. The source potential is, for example, the ground potential. As a result, the electric field that is applied to the GaN layer 20 between the drain finger part 202 and the gate electrode 50 can be relaxed, and the breakdown voltage can be increased.

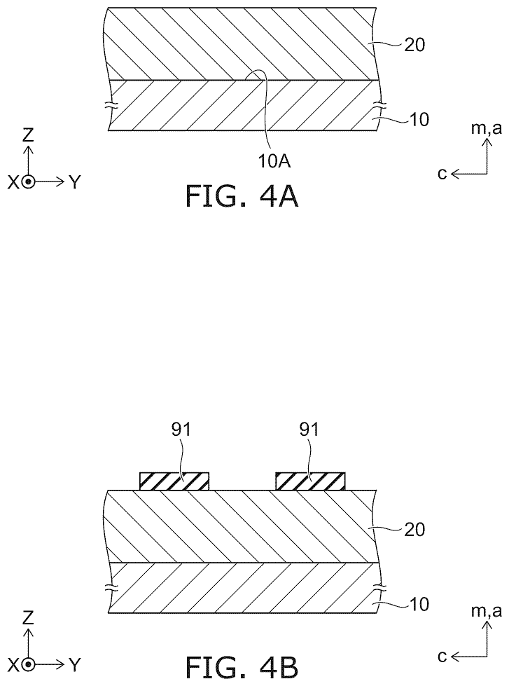

A method for manufacturing a semiconductor device of an embodiment will now be described with reference to FIGS. 4A to 9B.

As shown in FIG. 4A, the method for manufacturing the semiconductor device of the embodiment includes a process of forming the gallium nitride layer (the GaN layer) 20 on the non-polar surface 10A of the substrate 10. For example, the GaN layer 20 is grown on the m-surface or the a-surface of a gallium nitride substrate by MOCVD (metal organic chemical vapor deposition).

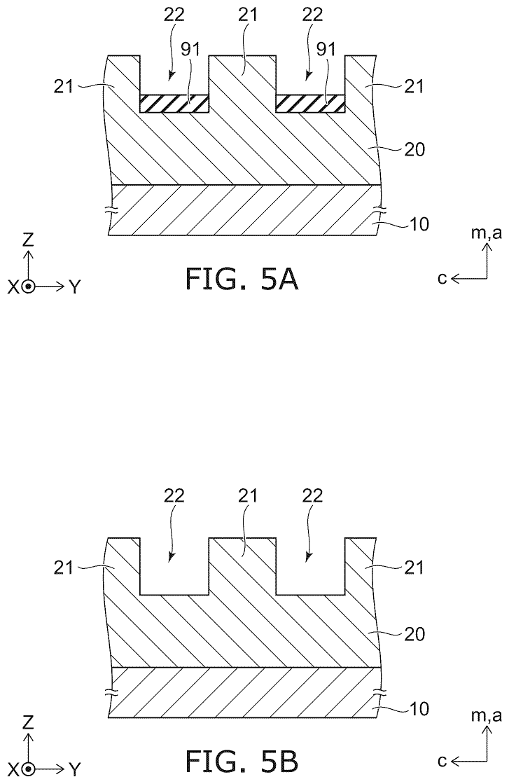

As shown in FIG. 5B, the method for manufacturing the semiconductor device of the embodiment includes a process of forming, in the GaN layer 20, the multiple fin parts 21 and a recess 22, which is positioned between the multiple fin parts 21. For example, as shown in FIG. 4B, a mask 91 is formed on the upper surface of the GaN layer 20. For example, a silicon oxide film can be used as the mask 91. While the mask 91 is in the formed state, GaN is grown by MOCVD on the upper surface of the GaN layer 20 exposed from under the mask 91 (FIG. 5A). Subsequently, the mask 91 is removed by, for example, wet etching.

As shown in FIG. 5B, the multiple fin parts 21 are separated from each other in the first direction Y, which is parallel to the c-axis direction. The recess 22 is positioned between the fin parts 21 adjacent to each other in the first direction Y. The multiple fin parts 21 and the multiple recesses 22 are alternately arranged in the first direction Y. The fin parts 21 and the recesses 22 extend in the second direction X.

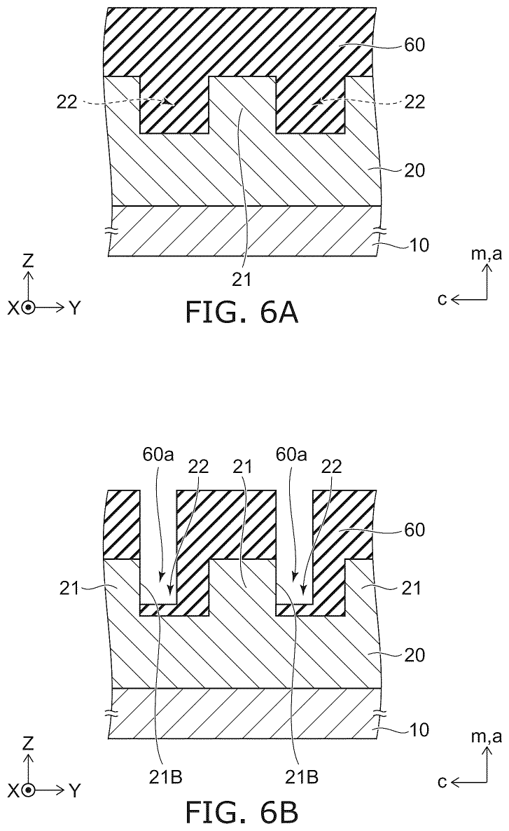

As shown in FIG. 6A, an insulating film 60 is filled into the recess 22. The insulating film 60 also covers the upper surface of the fin part 21. For example, a silicon nitride film can be formed by plasma CVD (Chemical Vapor Deposition) as the insulating film 60.

When manufacturing a semiconductor device that includes the p-type layer 70, a first opening 60a is formed in the insulating film 60 as shown in FIG. 6B. The first opening 60a includes a portion of the recess 22 adjacent to the N-surface 21B of the fin part 21. The N-surface 21B of the fin part 21 is exposed in the first opening 60a. For example, the first opening 60a can be formed by RIE (Reactive Ion Etching).

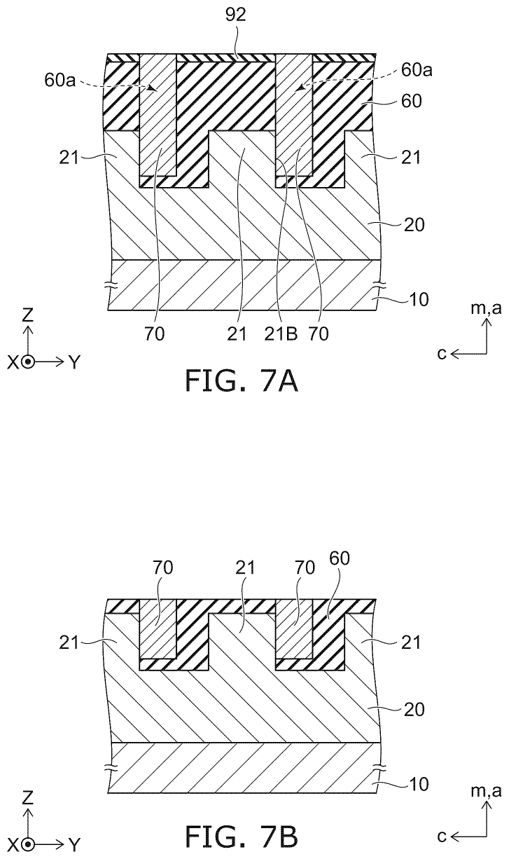

As shown in FIG. 7A, a second mask 92 is formed on the upper surface of the insulating film 60, and then the p-type layer (e.g., the p-type GaN layer) 70 is grown from the N-surface 21B exposed at the first opening 60a by MOCVD. The p-type layer 70 is formed inside the first opening 60a. Or, the p-type layer 70 may be formed by growing a GaN layer from the N-surface 21B, then ion-implanting a p-type impurity (e.g., Mg) into the GaN layer, and then activating by heat treatment. For example, a silicon oxide film can be used as the second mask 92.

After forming the p-type layer 70, the second mask 92 is removed and/or the upper surface of the p-type layer 70 and the upper surface of the insulating film 60 are planarized by CMP (Chemical Mechanical Polishing) (FIG. 7B).

The method for manufacturing the semiconductor device of the embodiment includes a subsequent process of forming the electron supply layer 30 at the Ga-surface 21A of the fin part 21.

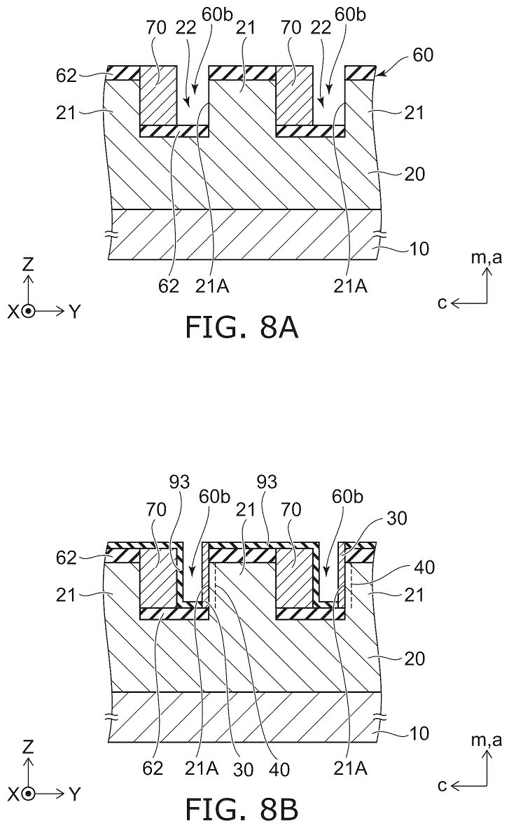

As shown in FIG. 8A, a second opening 60b is formed in the insulating film 60 by, for example, RIE. The second opening 60b includes a portion of the recess 22 adjacent to the Ga-surface 21A of the fin part 21. The Ga-surface 21A of the fin part 21 is exposed in the second opening 60b. At this time, the insulating film 60 that remains at the bottom surface of the recess 22 and the upper surface of the fin part 21 becomes the second insulating film 62 described above.

As shown in FIG. 8B, a third mask 93 is formed inside the second opening 60b. For example, a silicon oxide film can be used as the third mask 93. The Ga-surface 21A is not covered with the third mask 93 and is exposed in the second opening 60b. While the third mask 93 is in the formed state, the electron supply layer 30 is grown on the exposed Ga-surface 21A by, for example, MOCVD or ALD (Atomic Layer Deposition). For example, an aluminum gallium nitride (AlGaN) layer or an aluminum nitride (AlN) layer is grown as the electron supply layer 30. The piezoelectric polarization effect causes a distribution in the two-dimensional electron gas 40 in the GaN layer 20 at the vicinity of the interface with the electron supply layer 30 (the Ga-surface 21A).

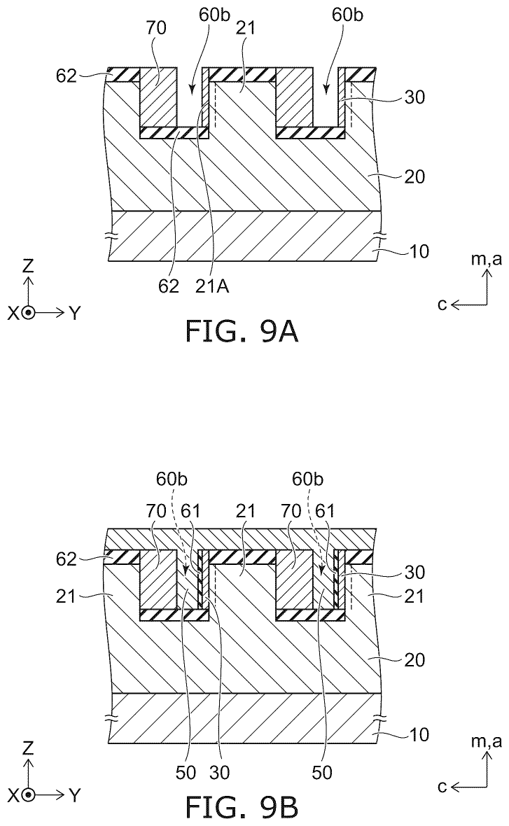

After forming the electron supply layer 30, the third mask 93 is removed, and/or the upper surface of the second insulating film 62, the upper surface of the p-type layer 70, and the upper surface of the electron supply layer 30 are planarized by CMP (FIG. 9A).

As shown in FIG. 9B, the method for manufacturing the semiconductor device of the embodiment includes a subsequent process of forming the gate electrode 50 inside the second opening 60b to face the electron supply layer 30 via the first insulating film 61.

First, the first insulating film 61 is formed at the surface of the electron supply layer 30 at the side opposite to the surface contacting the Ga-surface 21A. A silicon nitride film can be formed as the first insulating film 61 by, for example, CVD.

After forming the first insulating film 61, the gate electrode 50 is formed inside the second opening 60b to contact the p-type layer 70 and the first insulating film 61. For example, a conductive film that includes at least one selected from the group consisting of TiN, TiW, and polycrystalline silicon is formed as the gate electrode 50. For example, the TIN film and the TiW film can be formed by sputtering. For example, the polycrystalline silicon film can be formed by CVD. After forming the conductive film, the conductive film that is formed on the upper surface of the second insulating film 62, the upper surface of the p-type layer 70, the upper surface of the first insulating film 61, and the upper surface of the electron supply layer 30 is removed by, for example, CMP (Chemical Mechanical Polishing).

While certain embodiments of the inventions have been described, these embodiments have been presented by way of example only, and are not intended to limit the scope of the inventions. These novel embodiments may be embodied in a variety of other forms; and various omissions, substitutions, and changes may be made without departing from the spirit of the inventions. Such embodiments and their modifications are within the scope and spirit of the inventions, and are within the scope of the inventions described in the claims and their equivalents.

What is claimed is:

1. A semiconductor device, comprising:
a substrate;
a gallium nitride layer located on a non-polar surface of the substrate, the gallium nitride layer including a plurality of fin parts separated from each other in a first direction parallel to a c-axis direction, the plurality of fin parts extending in a second direction orthogonal to the first direction;
an electron supply layer located at a Ga-surface of at least one of the fin parts;
a source finger part extending in the first direction and contacting the electron supply layer;
a drain finger part extending in the first direction and contacting the electron supply layer, the drain finger part being separated from the source finger part in the second direction;
a gate electrode positioned between the source finger part and the drain finger part in the second direction, the gate electrode facing the electron supply layer in the first direction; and
a first insulating film located between the gate electrode and the electron supply layer.

2. The semiconductor device according to claim 1, further comprising:
a p-type layer located at a N-surface of at least one of the fin parts.

3. The semiconductor device according to claim 2, wherein
the p-type layer contacts the gate electrode.

4. The semiconductor device according to claim 2, wherein
the p-type layer is a p-type GaN layer.

5. The semiconductor device according to claim 3, wherein
the p-type layer is a p-type GaN layer.

6. The semiconductor device according to claim 1, further comprising:
a field plate electrode positioned between the gate electrode and the drain finger part in the second direction and positioned between adjacent fin parts among the plurality of fin parts in the first direction.

7. The semiconductor device according to claim 6, wherein
the field plate electrode is electrically connected to the source finger part.

8. The semiconductor device according to claim 1, wherein
C>A+B is satisfied,
A is a width in the first direction of the fin part,
B is a distance between adjacent fin parts among the plurality of fin parts in the first direction, and
C is a height of the fin part.

9. The semiconductor device according to claim 1, wherein
the electron supply layer is an aluminum gallium nitride layer or an aluminum nitride layer.

10. The semiconductor device according to claim 1, wherein
a distance in the second direction between the drain finger part and the gate electrode is greater than a distance in the second direction between the source finger part and the gate electrode.

11. A method for manufacturing a semiconductor device, the method comprising:
forming a gallium nitride layer on a non-polar surface of a substrate;
forming a plurality of fin parts and a recess in the gallium nitride layer, the plurality of fin parts being separated from each other in a first direction parallel to a c-axis direction, the plurality of fin parts extending in a second direction orthogonal to the first direction, the recess being positioned between the plurality of fin parts;
forming an electron supply layer at a Ga-surface of at least one of the fin parts; and
forming a gate electrode facing the electron supply layer via a first insulating film inside the recess.

12. The method according to claim 11, further comprising:
forming a p-type layer at a N-surface of at least one of the fin parts.

13. The method according to claim 12, wherein
the gate electrode is formed after the forming of the p-type layer so that the gate electrode contacts the p-type layer and the first insulating film inside the recess.
